(19) United States
(12) Patent Application Publication
(10) Pub. No.: US 2024/0234519 A9
(43) Pub. Date: Jul. 11, 2024

(54) Field-Effect Transistor and Manufacturing Method Therefor

(71) Applicant: Nippon Telegraph and Telephone Corporation, Tokyo (JP)

(72) Inventors: Takuya Tsutsumi, Musashino-shi, Tokyo (JP); Hideaki Matsuzaki, Musashino-shi, Tokyo (JP)

(21) Appl. No.: 18/548,165

(22) PCT Filed: Mar. 29, 2021
(86) PCT No.: PCT/JP2021/013228

§ 371 Date: Aug. 28, 2023

(51) Int. Cl. H01L 29/40; H01L 29/205; H01L 29/417; H01L 29/423; H01L 29/66; H01L 29/778

(52) U.S. Cl. CPC H01L 29/401; H01L 29/205; H01L 29/41766; H01L 29/42316; H01L 29/66462; H01L 29/7786

(57) ABSTRACT

A field effect transistor includes a first etching stop structure and a second etching stop structure. The first etching stop structure is formed on a first side surface of a recess region that is a boundary between a cap layer on a side of a source electrode and the recess region. The second etching stop structure is formed on a second side surface of the recess region that is a boundary between the cap layer on a side of a drain electrode and the recess region.

### TECHNICAL FIELD

The present invention relates to a field effect transistor and a method of manufacturing the same.

### BACKGROUND ART

In recent years, electronic devices for terahertz capable of handling a terahertz frequency band of 0.3 to 3.0 THz and integrated circuits have attracted attention as elemental technologies such as next-generation high-speed wireless communication, non-destructive internal inspection using three-dimensional imaging, and component analysis using electromagnetic wave absorption. Generally, as an electronic device having favorable high-frequency characteristics, a field effect transistor made of a compound semiconductor having particularly high electron mobility in physical properties is used.

A field effect transistor includes a semiconductor substrate, a gate electrode formed on a surface of the semiconductor substrate, and a source electrode and a drain electrode formed on both sides of the gate electrode. In particular, in a high electron mobility transistor (HEMI) having excellent high-frequency characteristics, for example, a configuration in which a buffer layer, a channel layer, a barrier layer, a stopper layer, and a cap layer are laminated on a semiconductor substrate is used. A carrier supply layer is formed on the barrier layer side with respect to the channel layer or on the buffer layer side with respect to the channel layer. In such a configuration, a position or a doping amount of the carrier supply layer is designed according to the energy band design.

When a potential is applied to the gate electrode, the concentration of a two-dimensional electron gas is modulated by supplying carriers from the carrier supply layer to the channel layer according to the intensity of the applied potential, and electrons move through a conduction channel formed between the source electrode and the drain electrode. In the structure of the HEMI, the channel layer and the electron supply layer through which the carriers travel are spatially separated, and scattering due to impurities is suppressed. With this configuration, the electron mobility can be improved, and as a result, a terahertz operation can be realized.

In order to apply the HEMI to a terahertz integrated circuit, it is necessary not only to improve high-frequency characteristics but also to improve uniformity of a device structure and operate an integrated circuit with good yield according to a circuit design.

For example, in Non Patent Literature 1, after a resist pattern for forming a gate electrode is formed, an opening is formed by etching a gate insulating film by using the resist pattern as a mask, and after the resist is removed, recess etching of a cap layer is performed by using the formed opening as a mask. Thereafter, a stopper layer or a barrier layer in addition to the stopper layer is etched in a depth direction through dry etching using an Ar gas, and then, a gate electrode is formed to form a field effect transistor structure in which a gate-channel distance is reduced, and thus an HEMT is manufactured.

In [Patent Literature 1], an asymmetric recess structure is formed by forming an extra recess opening on a drain side of a gate insulating film such that a drain-side recess region is wider than a source-side recess region, and infiltrating a recess forming etching solution from both the gate opening and the recess opening. A carrier is depleted over a wide region on the drain electrode side to reduce the drain conductance and improve high-frequency characteristics.

### CITATION LIST

### Patent Literature

Patent Literature 1: Japanese Patent No. 3715557

### Non Patent Literature

Non Patent Literature 1: T. Suemitsu et al., “Improved Recessed-Gate Structure for Sub-0.1-μm-Gate InP-Based High Electron Mobility Transistors”, Japanese Journal of Applied Physics, vol. 37, no. 1363-1372, 1998.

### SUMMARY OF INVENTION

### Technical Problem

However, the technique described above has a problem that it is difficult to control an etching amount because wet etching is used to form the recess region. For example, in the technique disclosed in Patent Literature 1, an opening for asymmetric recess formation and a gate insulating film opening for gate electrode formation are simultaneously formed, and wet etching is performed for a predetermined number of seconds to form more recess regions on the drain side.

However, an etching rate during the wet etching sensitively varies depending on not only the concentration and composition ratio of an etching solution but also a temperature, stirring conditions, convection of the solution, and the like. The etching rate greatly varies depending on crystal quality or a surface state of the cap layer to be etched and removed. Thus, a variation occurs in a recess etching amount, and a considerable variation also occurs in high-frequency characteristics. Typically, in an integrated circuit in which at least several tens to several hundreds of HEMTs are integrated, a yield is reduced, and a barrier to terahertz application is caused.

The present invention has been made to solve the above problems, and an object thereof is to accurately control an etching amount for forming a recess to manufacture a field effect transistor.

### Solution to Problem

According to the present invention, there is provided a field effect transistor including a buffer layer, a channel layer, a barrier layer, a carrier supply layer, and a cap layer formed on a semiconductor substrate; a source electrode and a drain electrode formed to be separated from each other on the cap layer; an insulating layer formed on the cap layer between the source electrode and the drain electrode and having an opening; a recess region formed in the cap layer between the source electrode and the drain electrode; a gate electrode disposed between the source electrode and the drain electrode, formed on the insulating layer, and partially fitted into the recess region through the opening; and an etching stop structure formed on at least one of a first side surface of the recess region that is a boundary between the cap layer on the source electrode side and the recess region and a second side surface of the recess region that is a boundary between the cap layer on the drain electrode side and the recess region.

According to the present invention, there is provided a method of manufacturing a field effect transistor, including a first step of forming a buffer layer, a channel layer, a barrier layer, a carrier supply layer, and a cap layer on a semiconductor substrate; a second step of forming a source electrode and a drain electrode to be separated from each other on the cap layer; a third step of forming a groove extending in a gate width direction in the cap layer at a position corresponding to at least one of a boundary on a side of the source electrode in a region used as a recess region and a boundary on a side of the drain electrode in a region used as a recess region; a fourth step of forming an etching stop structure on at least one of a first side surface of the recess region that is a boundary between the cap layer on the source electrode side of the groove and the recess region and a second side surface of the recess region that is a boundary between the cap layer on the drain electrode side of the groove and the recess region; a fifth step of forming an insulating layer between the source electrode and the drain electrode on the cap layer in which the groove is formed; a sixth step of forming an opening in the insulating layer; a seventh step of forming the recess region in the cap layer below the opening by etching the cap layer from the opening to the etching stop structure in a direction of the source electrode and a direction of the drain electrode in a plan view of a part of the cap layer through an etching process using the insulating layer having the opening as a mask; and an eighth step of depositing a gate electrode material on the insulating layer to form a gate electrode that is disposed on the insulating layer, is partially fitted into the recess region through the opening, and includes a main portion made of the gate electrode material and a plunged portion disposed between the main portion and the barrier layer.

### Advantageous Effects of Invention

As described above, according to the present invention, since the etching stop structure is provided, it is possible to manufacture a field effect transistor by accurately controlling an etching amount for forming a recess. According to the present invention, a recess etching amount can be accurately controlled.

### BRIEF DESCRIPTION OF DRAWINGS

FIG. 1 is a sectional view illustrating a configuration of a field effect transistor according to an embodiment of the present invention.

FIG. 2 is a sectional view illustrating a configuration of another field effect transistor according to the embodiment of the present invention.

FIG. 3 is a sectional view illustrating a configuration of another field effect transistor according to the embodiment of the present invention.

FIG. 4 is a sectional view illustrating a configuration of still another field effect transistor according to the embodiment of the present invention.

FIG. 5 is a sectional view illustrating a configuration of still another field effect transistor according to the embodiment of the present invention.

FIG. 6A is a sectional view illustrating a state of a field effect transistor in an intermediate step for describing a method of manufacturing the field effect transistor according to the embodiment of the present invention.

FIG. 6B is a sectional view illustrating a state of the field effect transistor in an intermediate step for describing a method of manufacturing the field effect transistor according to the embodiment of the present invention.

FIG. 6C is a sectional view illustrating a state of the field effect transistor in an intermediate step for describing a method of manufacturing the field effect transistor according to the embodiment of the present invention.

FIG. 6D is a sectional view illustrating a state of the field effect transistor in an intermediate step for describing a method of manufacturing the field effect transistor according to the embodiment of the present invention.

FIG. 6E is a sectional view illustrating a state of the field effect transistor in an intermediate step for describing a method of manufacturing the field effect transistor according to the embodiment of the present invention.

FIG. 6F is a sectional view illustrating a state of the field effect transistor in an intermediate step for describing a method of manufacturing the field effect transistor according to the embodiment of the present invention.

### DESCRIPTION OF EMBODIMENTS

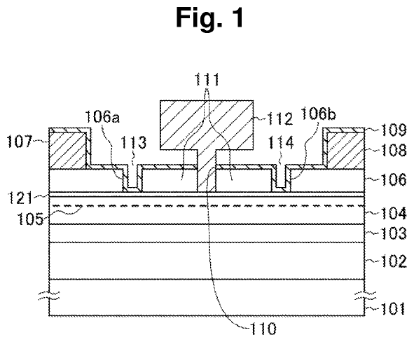

Hereinafter, a field effect transistor according to an embodiment of the present invention will be described with reference to FIG. 1.

The field effect transistor first includes a buffer layer 102, a channel layer 103, a barrier layer 104, a carrier supply layer 105, and a cap layer 106 formed on a semiconductor substrate 101. An etching stop layer 121 formed between the carrier supply layer 105 and the cap layer 106 may also be provided. The etching stop layer 121 may be made of a material having high etching selectivity with respect to an etching solution used for etching the cap layer 106 for forming a recess region 111.

For example, the semiconductor substrate 101 may be made of semi-insulating InP. The buffer layer 102 includes InAlAs and may have a thickness of 100 to 300 nm. The channel layer 103 may be made of InGaAs and have a thickness of 5 to 20 nm. The barrier layer 104 may be made of InAlAs and have a thickness of 5 to 20 nm. The cap layer 106 may be made of, for example, InGaAs doped with Si to 1×10¹⁹ to 2×10¹⁹ cm⁻³. The carrier supply layer 105 may be a layer in which the barrier layer 104 is doped with Si as an impurity to 1×10¹⁹ cm⁻³ through well-known sheet doping.

The etching stop layer 121 may be made of InP and have a thickness of 2 to 5 nm. The channel layer 103 made of InGaAs may be etched by using an etching solution such as citric acid. On the other hand, the etching stop layer 121 made of InP is hardly etched by a citric acid-based etching solution, and can thus be used as a layer for stopping etching.

The field effect transistor includes a source electrode 107 and a drain electrode 108 formed to be separated from each other on the cap layer 106. The source electrode 107 and the drain electrode 108 are formed with a region serving as the recess region 111 interposed therebetween. The source electrode 107 and the drain electrode 108 may include, for example, a laminated structure of a metal such as Ti, Pt, Au, or Ni.

The field effect transistor includes an insulating layer 109 formed on the cap layer 106 between the source electrode 107 and the drain electrode 108. The insulating layer 109 has an opening 110. In this example, the insulating layer 109 is formed to cover the source electrode 107 and the drain electrode 108. The insulating layer 109 may be made of an insulating material such as SiO₂, SiN, Al₂O₃, or HfO₂.

The field effect transistor includes the recess region 111 and a gate electrode 112. The recess region 111 is formed in the cap layer 106 between the source electrode 107 and the drain electrode 108. The recess region 111 may be a recess, a groove, or a through-hole having a relatively large diameter formed in the cap layer 106. The gate electrode 112 is disposed between the source electrode 107 and the drain electrode 108, is formed on the insulating layer 109, and is partially fitted into the recess region 111 through the opening 110. The gate electrode 112 is formed from the opening 110 to the etching stop layer 121 in the depth direction. The gate electrode 112 may be mainly formed of a composite structure of Ti, Pt, Au, and Mo. In order to realize a short gate length while reducing the gate resistance as much as possible, the gate electrode 112 may be a T-type, a Y-type, or a P-type in which an upper portion is wider than a lower portion in a plan view.

The field effect transistor includes an etching stop structure 113 and an etching stop structure 114. The etching stop structure 113 is formed on a first side surface 106a of the recess region 111 that is a boundary between the cap layer 106 on the side of the source electrode 107 and the recess region 111. The etching stop structure 114 is formed on a second side surface 106b of the recess region 111 that is a boundary between the cap layer 106 on the side of the drain electrode 108 and the recess region 111.

The etching stop structure 113 and the etching stop structure 114 may be made of a material having high etching selectivity with respect to an etching solution used for etching the cap layer 106 for forming the recess region 111. The etching stop structure 113 and the etching stop structure 114 may be made of, for example, an insulating material such as SiO₂, SiN, Al₂O₃, or HfO₂. In this example, the etching stop structure 113 and the etching stop structure 114 are configured by a part of the insulating layer 109 formed to extend from above the cap layer 106 to the first side surface 106a and the second side surface 106b.

By providing the etching stop structure 113 and the etching stop structure 114, it is possible to accurately control an etching amount of the cap layer 106 for forming the recess region 111 in the directions of the source electrode 107 and the drain electrode 108. According to the embodiment, the etching stop layer 121 is also used, and thus an etching amount in the thickness direction of the cap layer 106 for forming the recess region 111 can also be accurately controlled.

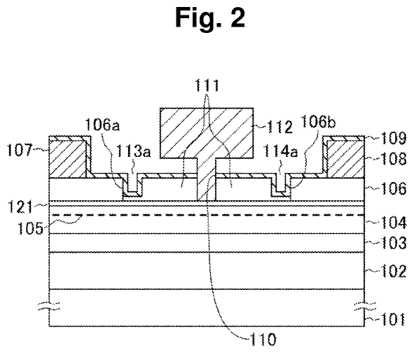

The etching stop structure 113 and the etching stop structure 114 may be formed to penetrate the cap layer 106. However, as illustrated in FIG. 2, an etching stop structure 113a and an etching stop structure 114a may be formed so not to penetrate the cap layer 106 but to extend to the middle of the cap layer 106 in the thickness direction. Also in this configuration, in the etching stop structure 113 and the etching stop structure 114, an infiltration rate of an etching solution in the directions of the source electrode 107 and the drain electrode 108 is restricted (suppressed), and an etching amount in the directions of the source electrode 107 and the drain electrode 108 can be controlled.

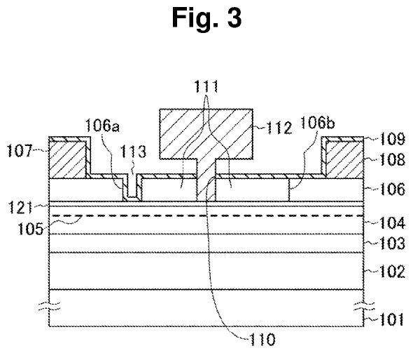

As illustrated in FIG. 3, the etching stop structure 113 may be formed only on the first side surface 106a that is a boundary between the cap layer 106 on the side of the source electrode 107 and the recess region 111. According to this configuration, in an etching process for forming the recess region, etching of the recess region 111 is stopped at a certain distance on the source electrode side, more recess etched regions are formed on the drain electrode side, and thus the recess region on the source electrode side and the recess region on the drain electrode side can be formed asymmetrically. Similarly, an etching stop structure (not illustrated) may be formed only on the second side surface 106b that is a boundary between the cap layer 106 on the side of the drain electrode 108 and the recess region 111.

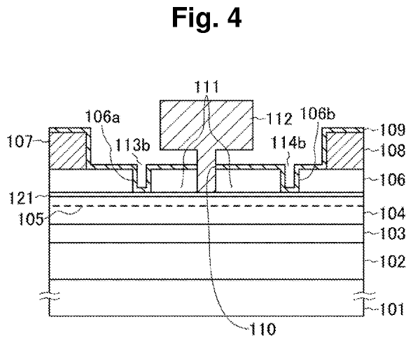

As illustrated in FIG. 4, a gap between the opening 110 (gate electrode 112) and the second side surface 106b (etching stop structure 113b) may be larger than a gap between the opening 110 (gate electrode 112) and the first side surface 106a (etching stop structure 114b). As described above, the field effect transistor having the asymmetric recess structure with reduced drain conductance and excellent high-frequency characteristics can be achieved.

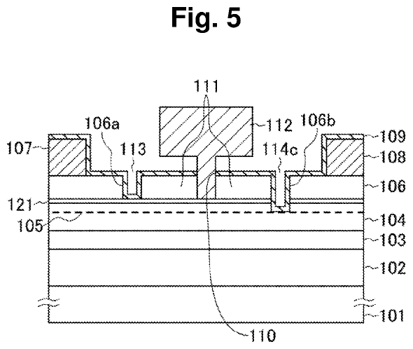

As illustrated in FIG. 5, an etching stop structure 114c may be formed by entering the lower layer of the cap layer 106 in the thickness direction. For example, the etching stop structure 114c may be formed at a depth halfway through the etching stop layer 121 or the barrier layer 104. With this configuration, the portion of the recess region 111 on the drain electrode side is formed to the depth of the barrier layer 104, and thus carrier depletion in the drain region can reduce the drain conductance and improve the high-frequency characteristics. The etching stop structure on the source electrode side may also be formed by entering the lower layer of the cap layer 106 in the thickness direction.

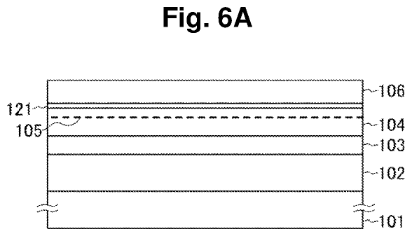

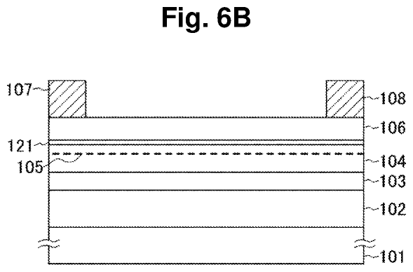

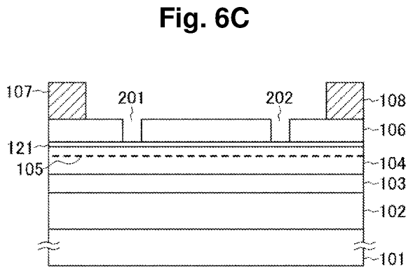

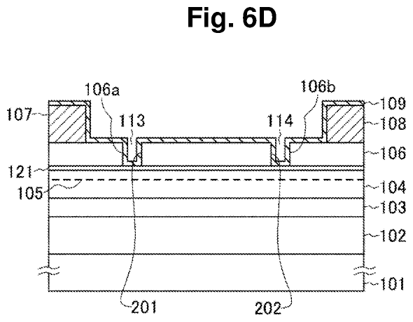

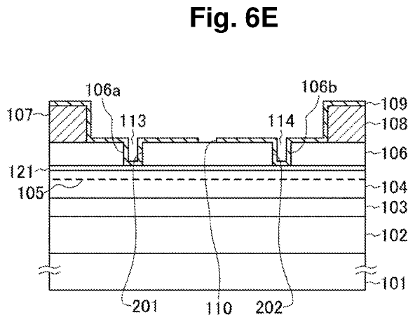

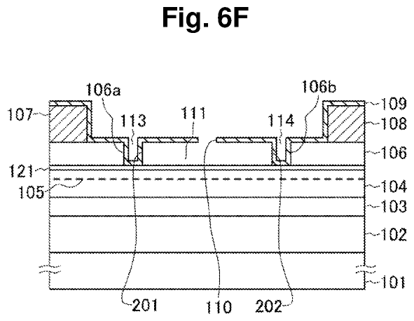

Next, a field effect transistor according to an embodiment of the present invention and a method of manufacturing the field effect transistor will be described with reference to FIGS. 6A to 6F.

First, as illustrated in FIG. 6A, the buffer layer 102, the channel layer 103, the barrier layer 104, the carrier supply layer 105, and the cap layer 106 are formed on a semiconductor substrate 101 (first step). In this example, in the first step, the buffer layer 102, the channel layer 103, the barrier layer 104, the carrier supply layer 105, an etching stop layer 121, and the cap layer 106 are formed on the semiconductor substrate 101.

For example, on the semiconductor substrate 101, the buffer layer 102 made of InAlAs and having a layer thickness of 100 to 300 nm, the channel layer 103 made of InGaAs and having a layer thickness of 5 to 20 nm, the barrier layer 104 made of InAlAs and having a layer thickness of 5 to 20 nm, and the cap layer 106 made of InGaAs doped with Si to 1×10¹⁹ to 2×10¹⁹ cm⁻³ are sequentially laminated through crystal growth by using a metal organic chemical vapor deposition method, a molecular beam epitaxy method, or the like. In the barrier layer 104, a carrier supply layer 105 doped with Si by 1×10¹⁹ cm⁻³ as an impurity is formed by well-known sheet doping. The etching stop layer 121 made of InP and having a layer thickness of 2 to 5 nm is formed between the carrier supply layer 105 and the cap layer 106.

Next, as illustrated in FIG. 6B, the source electrode 107 and the drain electrode 108 are formed to be separated from each other on the cap layer 106 (second step). For example, Ti/Pt/Au is deposited on the cap layer 106 to form a metal film, and this metal film is patterned by using a known photolithography technique and etching technique to form the source electrode 107 and the drain electrode 108. The source electrode 107 and the drain electrode 108 may also be formed by using a known lift-off method. The source electrode 107 and the drain electrode 108 are in ohmic contact with the cap layer 106.

Next, as illustrated in FIG. 6C, grooves 201 and 202 extending in a gate width direction is formed in the cap layer 106 at a position corresponding to at least one of a boundary on the side of source electrode 107 in a region to be the recess region 111 and a boundary on the side of the drain electrode 108 in a region to be the recess region 111 (third step).

First, a mask layer having openings in the portions of the grooves 201 and 202 is formed by using a known electron beam lithography technique or a known photolithography technique. The mask layer may be made of a resist or an insulating material. Next, the cap layer 106 is selectively etched by using the mask layer as a mask to form the grooves 201 and 202. For example, the grooves 201 and 202 may be formed by using an etching solution using citric acid, phosphoric acid, or the like. The grooves 201 and 202 may be formed through dry etching using Cl, HI, HBr, or the like.

After the etching process described above, the mask layer is removed, and then, a layer of a material for forming an etching stop structure is formed inside the groove 201 and the groove 202, and the etching stop structure 113 and the etching stop structure 114 are formed (fourth step). For the formation of this layer, for example, a well-known conformal method may also be used. Examples of the material described above include SiO₂ and SiN. The layer may be formed of an insulating layer that is made of Al₂O₃, HfO₂, or the like which can be formed through deposition according to an atomic layer deposition method (ALD method) or the like.

Next, the insulating layer 109 is formed between the source electrode 107 and the drain electrode 108 on the cap layer 106 in which the grooves 201 and 202 are formed (fifth step). Here, the insulating layer 109 is also formed to cover the source electrode 107 and the drain electrode 108. For example, the insulating layer 109 may be formed by depositing an insulating material such as SiO₂ or SiNₓ according to a well-known plasma CVD method or the like.

As illustrated in FIG. 6D, the insulating layer 109 is formed on the cap layer 106 in which the groove 201 and the groove 202 are formed, and the insulating layer 109 is made to enter the recess region 111 in the groove 201 and the groove 202, so that the etching stop structure 113 and the etching stop structure 114 can be formed (fourth step and fifth step).

Next, as illustrated in FIG. 6E, the opening 110 is formed in the insulating layer 109 (sixth step). For example, the opening 110 may be formed by using a known electron beam lithography technique, photolithography technique, or etching technique.

Next, as illustrated in FIG. 6F, the recess region 111 is formed in the cap layer 106 below the opening 110 (seventh step). The recess region 111 may be formed by etching the cap layer 106 from the opening 110 to the etching stop structure in the direction of the source electrode 107 and the direction of the drain electrode 108 in a plan view of a part of the cap layer 106 through an etching process using the insulating layer 109 having the opening 110 as a mask. In this step, the recess region 111 is formed by etching the cap layer to the etching stop layer 121 in the thickness direction.

Thereafter, by forming the gate electrode 112 (eighth step), the field effect transistor illustrated in FIG. 1 is obtained. For example, by depositing a gate electrode material on the insulating layer 109, it is possible to form the gate electrode 112 that is disposed on the insulating layer 109, is partially fitted into the recess region 111 through the opening 110, and includes a main portion made of the gate electrode material and a plunged portion disposed between the main portion and the barrier layer 104. The gate electrode material may be deposited according to, for example, a vacuum vapor deposition method or a sputtering method.

As described above, according to the present invention, since the etching stop structure is provided, it is possible to manufacture a field effect transistor by accurately controlling an etching amount for forming the recess. According to the present invention, a recess etching amount can be accurately controlled. By employing the structure in which a position of the etching stop structure on the source side is away from the gate electrode compared with the etching stop structure on the drain side, it is also possible to implement the field effect transistor having an asymmetric recess structure with reduced drain conductance and excellent high-frequency characteristics. With these simple means and structures, it is possible to manufacture a field effect transistor having excellent high-frequency characteristics with good controllability.

The present invention is not limited to the embodiment described above, and it is obvious that many modifications and combinations can be made by a person skilled in the art within the technical idea of the present invention.

### REFERENCE SIGNS LIST

101 Semiconductor substrate
102 Buffer layer
103 Channel layer
104 Barrier layer
105 Carrier supply layer
106a First side surface
106b Second side surface
107 Source electrode
108 Drain electrode
109 Insulating layer
110 Opening
111 Recess region
112 Gate electrode
113 Etching stop structure
114 Etching stop structure
121 Etching stop layer

1. A field effect transistor comprising:
a buffer layer, a channel layer, a barrier layer, a carrier supply layer, and a cap layer formed on a semiconductor substrate;
a source electrode and a drain electrode formed to be separated from each other on the cap layer;
an insulating layer formed on the cap layer between the source electrode and the drain electrode and having an opening;
a recess region formed in the cap layer between the source electrode and the drain electrode;
a gate electrode disposed between the source electrode and the drain electrode, formed on the insulating layer, and partially fitted into the recess region through the opening; and
an etching stop structure formed on at least one of a first side surface of the recess region that is a boundary between the cap layer on the source electrode side and the recess region and a second side surface of the recess region that is a boundary between the cap layer on the drain electrode side and the recess region.

2. The field effect transistor according to claim 1, wherein a gap between the opening and the second side surface is larger than a gap between the opening and the first side surface.

3. The field effect transistor according to claim 1, wherein the etching stop structure is formed to enter a lower layer of the cap layer in a thickness direction.

4. The field effect transistor according to claim 1, further comprising an etching stop layer formed between the carrier supply layer and the cap layer.

5. A method of manufacturing a field effect transistor, comprising:
a first step of forming a buffer layer, a channel layer, a barrier layer, a carrier supply layer, and a cap layer on a semiconductor substrate;
a second step of forming a source electrode and a drain electrode to be separated from each other on the cap layer;
a third step of forming a groove extending in a gate width direction in the cap layer at a position corresponding to at least one of a boundary on a side of the source electrode in a region used as a recess region and a boundary on a side of the drain electrode in a region used as a recess region;
a fourth step of forming an etching stop structure on at least one of a first side surface of the recess region that is a boundary between the cap layer on the source electrode side of the groove and the recess region and a second side surface of the recess region that is a boundary between the cap layer on the drain electrode side of the groove and the recess region;
a fifth step of forming an insulating layer between the source electrode and the drain electrode on the cap layer in which the groove is formed;
a sixth step of forming an opening in the insulating layer;
a seventh step of forming the recess region in the cap layer below the opening by etching the cap layer from the opening to the etching stop structure in a direction of the source electrode and a direction of the drain electrode in a plan view of a part of the cap layer through an etching process using the insulating layer having the opening as a mask; and
an eighth step of depositing a gate electrode material on the insulating layer to form a gate electrode that is disposed on the insulating layer, is partially fitted into the recess region through the opening, and includes a main portion made of the gate electrode material and a plunged portion disposed between the main portion and the barrier layer.

6. The method of manufacturing a field effect transistor according to claim 5, wherein the fourth step and the fifth step are performed by forming the insulating layer on the cap layer in which the groove is formed to allow the insulating layer to enter the recess region in the groove, and forming the etching stop structure on at least one of the first side surface of the recess region that is a boundary between the cap layer on the source electrode side and the recess region and the second side surface of the recess region that is a boundary between the cap layer on the drain electrode side and the recess region.

7. The method of manufacturing a field effect transistor according to claim 5, wherein
in the first step, the buffer layer, the channel layer, the barrier layer, the carrier supply layer, the etching stop layer, and the cap layer are formed on the semiconductor substrate, and
in the seventh step, the recess region is formed by performing etching to the etching stop layer in a thickness direction.

8. The field effect transistor according to claim 2, wherein the etching stop structure is formed to enter a lower layer of the cap layer in a thickness direction.

9. The field effect transistor according to claim 2, further comprising an etching stop layer formed between the carrier supply layer and the cap layer.

10. The field effect transistor according to claim 3, further comprising an etching stop layer formed between the carrier supply layer and the cap layer.

11. The method of manufacturing a field effect transistor according to claim 6, wherein
in the first step, the buffer layer, the channel layer, the barrier layer, the carrier supply layer, the etching stop layer, and the cap layer are formed on the semiconductor substrate, and
in the seventh step, the recess region is formed by performing etching to the etching stop layer in a thickness direction.
